(19) United States
(12) Patent Application Publication
(10) Pub. No.: US 2015/0054099 A1
(43) Pub. Date: Feb. 26, 2015

(54) PRESSURE SENSOR DEVICE AND ASSEMBLY METHOD

(71) Applicants: Kai Yun Yow, Petaling Jaya (MY); Poh Leng Eu, Petaling Jaya (MY); Chee Seng Foong, Sg Buloh (MY); Navas Khan Oratti Kalandar, Petaling Jaya (MY); Lan Chu Tan, Singapore (SG)

(72) Inventors: Kai Yun Yow, Petaling Jaya (MY); Poh Leng Eu, Petaling Jaya (MY); Chee Seng Foong, Sg Buloh (MY); Navas Khan Oratti Kalandar, Petaling Jaya (MY); Lan Chu Tan, Singapore (SG)

(21) Appl. No.: 13/975,359

(22) Filed: Aug. 25, 2013

(51) Int. Cl. H01L 29/84; H01L 25/00; H01L 21/56; H01L 25/18

(52) U.S. Cl. CPC H01L 29/84; H01L 25/18; H01L 25/50; H01L 21/56
USPC 257/417; 438/51

(57) ABSTRACT

A semiconductor sensor device is assembled using a pre-molded lead frame having first and second die flags. The first die flag includes a cavity. A pressure sensor die (P-cell) is mounted within the cavity and a master control unit die (MCU) is mounted to the second flag. The P-cell and MCU are electrically connected to leads of the lead frame with bond wires. The die attach and wire bonding steps are each done in a single pass. A mold pin is placed over the P-cell and then the MCU is encapsulated with a mold compound. The mold pin is removed leaving a recess that is next filled with a gel material. Finally a lid is placed over the P-cell and gel material. The lid includes a hole that that exposes the gel-covered active region of the pressure sensor die to ambient atmospheric pressure outside the sensor device.

### BACKGROUND OF THE INVENTION

The present invention relates generally to semiconductor sensor devices and, more particularly to a method of assembling a semiconductor pressure sensor device.

Semiconductor sensor devices, such as pressure sensors, are well known. Such devices use semiconductor pressure sensor dies. These dies are susceptible to mechanical damage during packaging and environmental damage when in use, and thus they must be carefully packaged. Further, pressure sensor dies, such as piezo resistive transducers (PRTs) and parameterized layout cells (P-cells), do not allow full encapsulation because that would impede their functionality.

FIG. 1(A) shows a cross-sectional side view of a conventional packaged semiconductor sensor device 100 having a metal lid 104. FIG. 1(B) shows a perspective top view of the sensor device 100 partially assembled, and FIG. 1(C) shows a perspective top view of the lid 104.

As shown in FIG. 1, a pressure sensor die (P-cell) 106, acceleration-sensing die (G-cell) 108, and master control unit die (MCU) 110 are mounted to a lead frame flag 112, electrically connected to lead frame leads 118 with bond wires (not shown), and covered with a pressure-sensitive gel 114, which enables the pressure of the ambient atmosphere to reach the pressure-sensitive active region on the top side of P-cell 106, while protecting all of the dies 106, 108, 110 and the bond wires from mechanical damage during packaging and environmental damage (e.g., contamination and/or corrosion) when in use. The entire die/substrate assembly is encased in mold compound 102 and covered by the lid 104, which has a vent hole 116 that exposes the gel-covered P-cell 106 to ambient atmospheric pressure outside the sensor device 100.

One problem with the sensor device 100 is the high manufacturing cost due to the use of a pre-molded lead frame, the metal lid 104, and the large volume of pressure-sensitive gel 114. Accordingly, it would be advantageous to have a more economical way to package dies in semiconductor sensor devices.

### BRIEF DESCRIPTION OF THE DRAWINGS

Embodiments of the present disclosure are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 shows a conventional packaged semiconductor sensor device having a metal lid;

FIG. 2 shows a semiconductor sensor device in accordance with an embodiment of the present invention; and

FIGS. 3-7 illustrate a method of assembling the sensor device of FIG. 2.

### DETAILED DESCRIPTION OF THE INVENTION

Detailed illustrative embodiments of the present disclosure are disclosed herein. However, specific structural and functional details disclosed herein are merely representative for purposes of describing example embodiments of the present disclosure. Embodiments of the present disclosure may be embodied in many alternative forms and should not be construed as limited to only the embodiments set forth herein. Further, the terminology used herein is for the purpose of describing particular embodiments only and is not intended to be limiting of example embodiments of the disclosure.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

One embodiment of the disclosure is a method for manufacturing a semiconductor sensor device, and another embodiment is the resulting semiconductor sensor device. At least two dies, comprising (i) a pressure sensor die having a pressure-sensitive active region and (ii) at least one other die, are die-bonded to a lead frame. The at least two dies are wire-bonded to corresponding leads of the lead frame using bond wires. A mold pin is placed over the pressure sensor die and its bond wires. Mold compound is applied to encapsulate the at least one other die and its bond wires. The mold pin is removed leaving a recess in the mold compound surrounding the pressure sensor die and its bond wires. Pressure-sensitive gel is applied in the recess to cover the active region of the pressure sensor die and its bond wires.

Another embodiment of the disclosure is a semiconductor sensor device comprising (i) a pre-molded lead frame, (ii) two or more dies including a pressure sensor die and at least one other die mounted to the lead frame, (iii) bond wires electrically interconnecting the two or more dies and the lead frame, (iv) mold compound encapsulating the at least one other die and its associated bond wires, and (v) pressure-sensitive gel covering an active region of the pressure sensor die and its associated bond wires. At least one lead of the lead frame is wire bonded to both (i) the pressure sensor die and (ii) the at least one other die, and the pressure sensor die is located in a cavity of a flag of the lead frame.

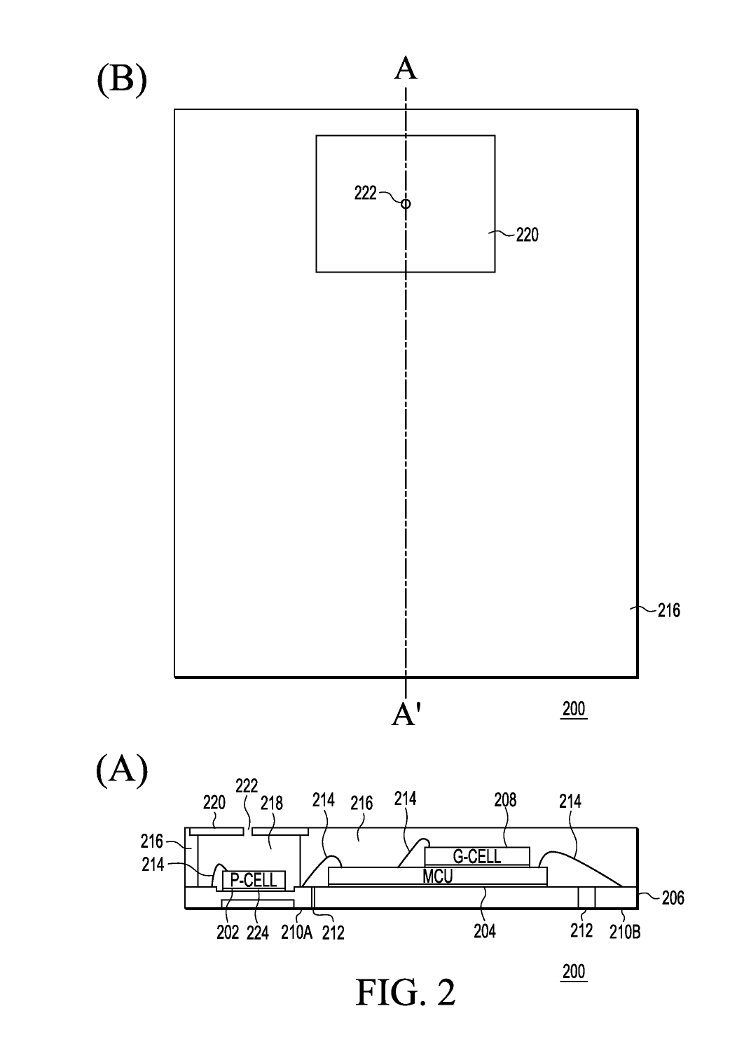

FIGS. 2(A) and 2(B) respectively show a cross-sectional side view and a top plan view of a packaged semiconductor sensor device 200 in accordance with an embodiment of the disclosure. The exemplary configuration of sensor device 200 forms a no-leads type package such as a quad flat no-leads (QFN) package. Note that alternative embodiments are not limited to QFN packages, but can be implemented for other package types, such as (without limitation) ball grid array (BGA) packages, molded array packages (MAP), and quad flat pack (QFP) or other leaded packages.

Sensor device 200 includes a pressure sensor die 202 and an ASIC die 204 mounted to (e.g., physically attached and electrically coupled to) a pre-molded lead frame 206, and an acceleration-sensing die 208 mounted to ASIC die 204. Pressure sensor die (aka P-cell) 202 is designed to sense ambient atmospheric pressure, while acceleration-sensing die (aka G-cell) 208 is designed to sense gravity or acceleration in one, two, or all three axes, depending on the particular implementation. ASIC die 204 functions as the master control unit (MCU) for P-cell 202 and G-cell 208 by, for example, controlling the operations of and processing signals generated by those two sensor dies. ASIC die 204 is synonymously referred to herein as MCU 204. Note that, in some embodiments, ASIC die 204 may implement both the functionality of an MCU and that of one or more other sensors, such as an acceleration-sensing G-cell, in which latter case, G-cell 208 may be omitted.

Pre-molded lead frame 206 comprises electrically conductive leads 210 embedded in an electrically insulating mold compound 212. Lead 210 may be formed of copper, an alloy of copper, a copper plated iron/nickel alloy, plated aluminum, or the like. Often, copper leads are pre-plated first with a nickel base layer, then a palladium mid layer, and finally with a very thin, gold upper layer. Mold compound 212 may be an epoxy or other suitable material.

Conventional, electrically insulating die-attach adhesive 224 may be used to attach (i) P-cell 202 and MCU 204 to lead frame 206 and (ii) G-cell 208 to MCU 204. Those skilled in the art will understand that suitable alternative means, such as die-attach tape, may be used to attach some or all of these dies. P-cell 202, MCU 204, and G-cell 208 are well known components of semiconductor sensor devices and thus detailed descriptions thereof are not necessary for a complete understanding of the disclosure.

The electrical interconnection between P-cell 202 and MCU 204 is provided via one or more shared lead(s) 210A of lead frame 206 by respective, associated bond wires 214 wire-bonded between (i) bond pads on P-cell 202 and MCU 204 and (ii) lead(s) 210A using a suitable, known wire-bonding process and suitable, known wire-bonding equipment. Similarly, the electrical interconnection between MCU 204 and G-cell 208 is provided by wire-bonding between other bond pads on MCU 204 and bond pads on G-cell 208. Furthermore, the electrical interconnection between MCU 204 and the outside world is provided via one or more lead(s) 210B of lead frame 206 by bond wires 214 wire-bonded between still other pads on MCU 204 and lead(s) 210B. Bond wires 214 are formed from a conductive material such as aluminium, gold, or copper, and may be either coated or uncoated. Note that, in alternative designs, G-cell 208 can be electrically connected to MCU 204 using suitable flip-chip, solder-bump techniques instead of or in addition to wire-bonding.

MCU 204, G-cell 208, and their associated bond wires 214 are encapsulated within a suitable mold compound 216. The mold compound may be a plastic, an epoxy, a silica-filled resin, a ceramic, a halide-free material, the like, or combinations thereof, as is known in the art.

A pressure-sensitive gel material 218, such as a silicon-based gel, is deposited over P-cell 214 and its associated bond wires 214, filling most of the recess formed in mold compound 216 around P-cell 214. Note that, in alternative implementations, less of gel material 218 may be applied within the recess as long as the pressure-sensitive active region (typically on the top side) of P-cell 214 and its associated bond wires are covered by the gel. Pressure-sensitive gel material 218 enables the pressure of the ambient atmosphere to reach the active region of P-cell 202, while protecting P-cell 202 and its associated bond wires 214 from (i) mechanical damage during packaging and (ii) environmental damage (e.g., contamination and/or corrosion) when in use. Examples of suitable pressure-sensitive gel material 218 are available from Dow Corning Corporation of Midland, Mich. The gel material may be dispensed with a nozzle of a conventional dispensing machine, as is known in the art.

A lid 220 having an opening or vent hole 222 is mounted over the gel-covered P-cell 202 fitting snugly into a seat formed within mold compound 216, thereby providing a protective cover for the P-cell. Vent hole 222 allows the ambient atmospheric pressure immediately outside sensor device 200 to reach (i) the pressure-sensitive gel material 218 and therethrough (ii) the active region of P-cell 202. Although shown centered in FIG. 2, vent hole 222 can be located anywhere within the area of lid 220. Vent hole 222 may be (pre-)formed in the lid by an suitable fabrication process such as drilling or punching.

Lid 220 is formed of a durable and stiff material, such as stainless steel, plated metal, or polymer, so that P-cell 202 is protected. Lid 220 is sized and shaped depending on the size and shape of P-cell 202 mounted to the lead frame under the lid. Accordingly, depending on the implementation, the lid may have any suitable shape, such as round, square, or rectangular.

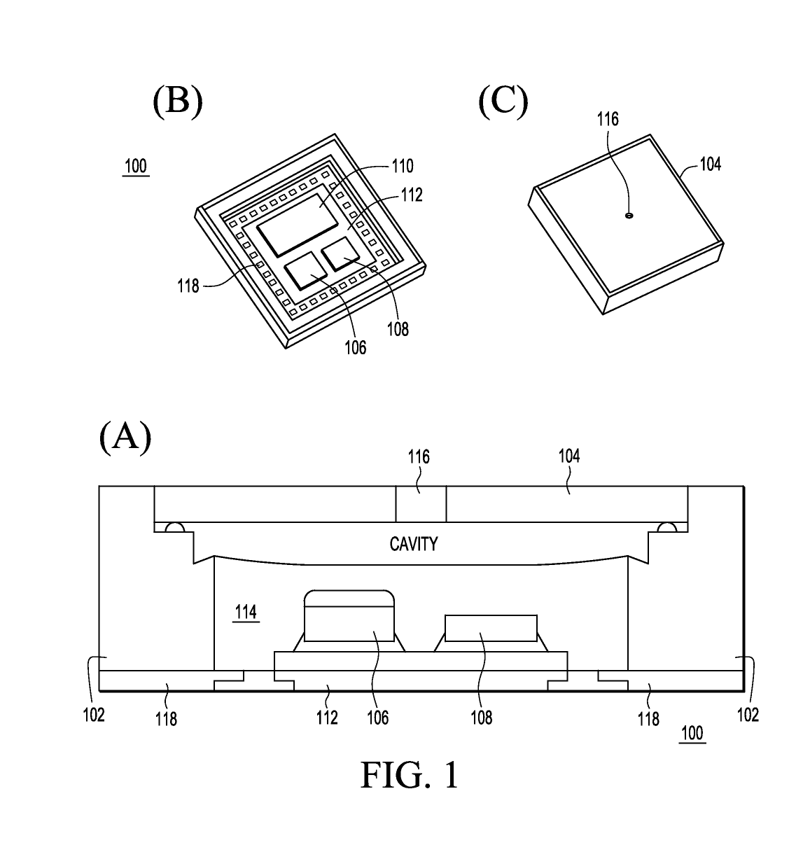

Sensor device 200 can be manufactured with less cost than comparable sensor devices, like those based on the conventional design of sensor device 100 of FIG. 1, because sensor device 200 can be manufactured with a smaller lid and with less pressure-sensitive gel.

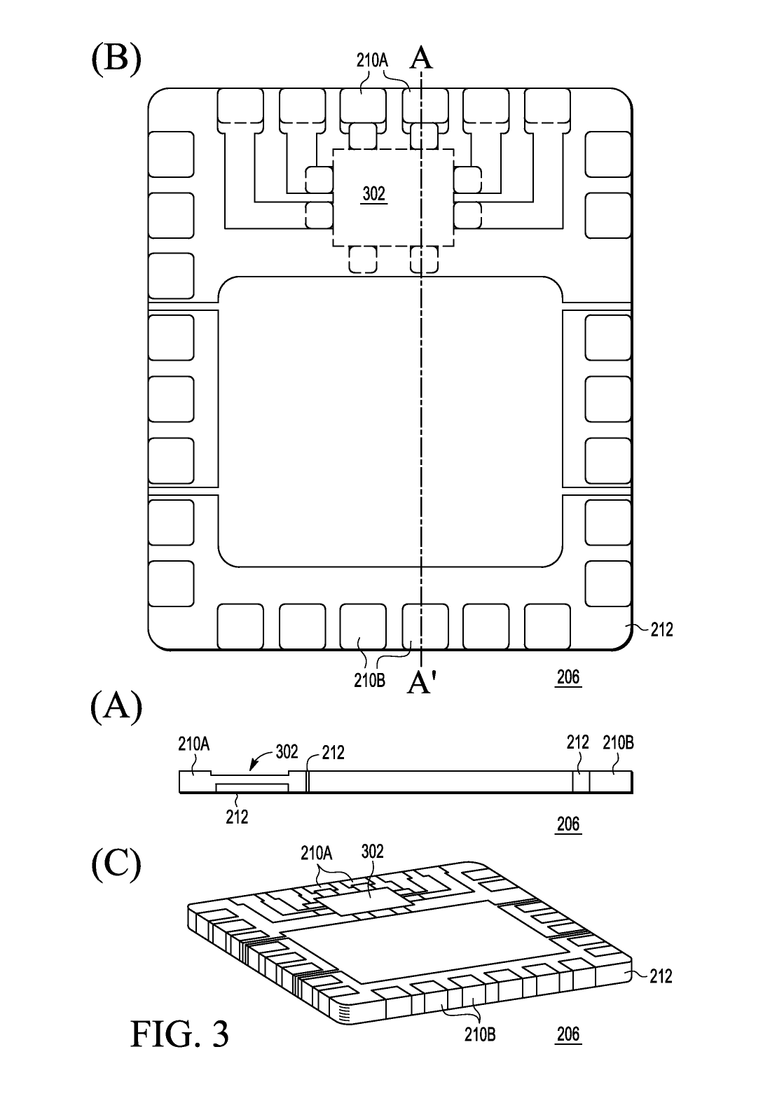

FIGS. 3-7 illustrate one possible process for manufacturing sensor device 200 of FIG. 2.

In particular, FIGS. 3(A), 3(B), and 3(C) respectively show a cross-sectional side view, a top plan view, and a three-dimensional (3D) perspective view of pre-molded lead frame 206 having electrically conductive leads 210 embedded in electrically insulating mold compound 212. Lead frame 206 also has a shallow recess 302 for receiving P-cell 202 of FIG. 2. The purpose of recess 302 is to prevent the die-attach material (e.g., 224 in FIG. 2) from flowing out to the wire-bonding area of leads 210.

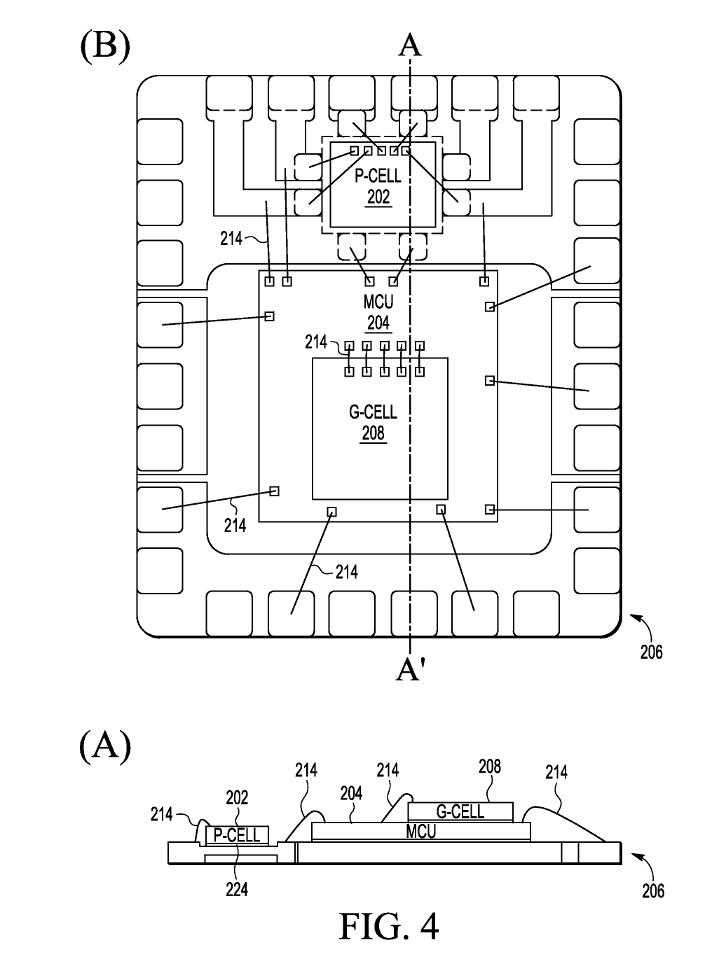

FIGS. 4(A) and 4(B) respectively show a cross-sectional side view and a top plan view of (i) P-cell 202 and MCU 204 mounted on and wire-bonded to lead frame 206 of FIG. 3 and (ii) G-cell 208 mounted on and wire-bonded to MCU 204. Note that the attachment or die-bonding of all of P-cell 202, MCU 204, and G-cell 204 can be achieved in a single die-bonding process step that includes the curing of the epoxy or other substance (e.g., die-attach tape) used to mount all of those dies in a single pass through a curing cycle (e.g., comprising heating and/or UV irradiation). Furthermore, (i) P-cell 202 and MCU 204 can be electrically connected to lead frame 206 and (ii) G-cell 208 can be electrically connected to MCU 204 all in a single pass though a wire-bonding cycle (or in a single wire-bonding process step).

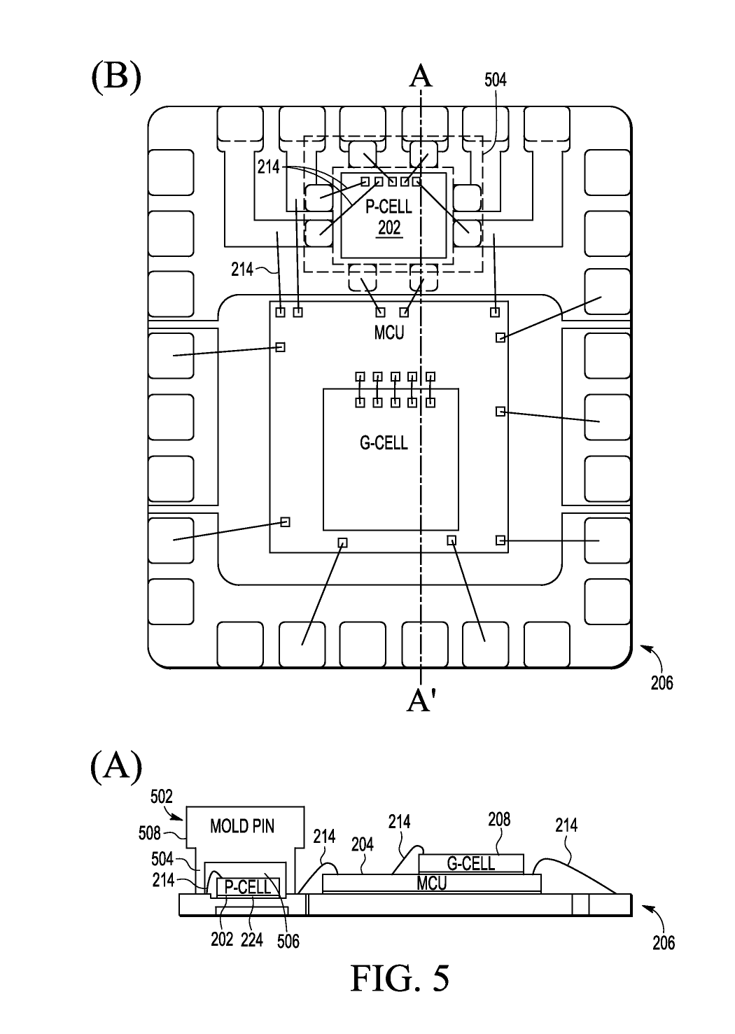

FIGS. 5(A) and 5(B) respectively show a cross-sectional side view and a partial X-ray, top plan view of the sub-assembly of FIG. 4 with mold pin 502 placed over P-cell 202. Mold pin 502 comprises (i) a lower portion 504 defining a cavity 506 that accommodates P-cell 202 as well as its associated bond wires 214 and (ii) an upper portion 508 whose outer dimensions are slightly larger than the outer dimensions of lower portion 504. In FIG. 5(B), the outline labeled 504 represents the periphery of the lower portion of mold pin 502 resting on lead frame 206. Note that the existence of the larger, upper portion 508 is optional.

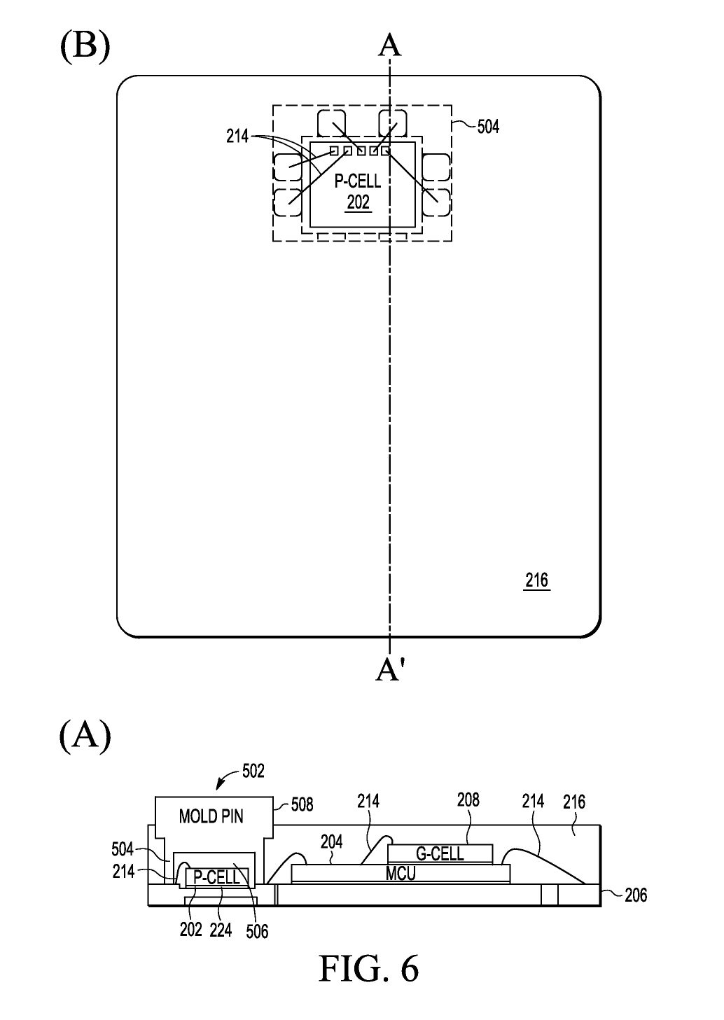

FIGS. 6(A) and 6(B) respectively show a cross-sectional side view and a partial X-ray, top plan view of the sub-assembly of FIG. 5 after the addition of mold compound 216 to encapsulate everything in the sub-assembly of FIG. 5 that is outside of the cavity defined by mold pin 502. One way of applying the mold compound 216 is using a mold insert of a conventional injection-molding machine, as is known in the art. The molding material is typically applied as a liquid polymer, which is then heated to form a solid by curing in a UV or ambient atmosphere. The molding material can also be a solid that is heated to form a liquid for application and then cooled to form a solid mold. Subsequently, an oven is used to cure the molding material to complete the cross linking of the polymer. In alternative embodiments, other encapsulating processes may be used. The mold pin 502 prevents mold compound 216 from seeping inside the cavity 506 and reaching the P-cell 202.

In the implementation shown in FIG. 6, the mold compound 216 is applied to a height that is slightly higher than the lower portion 504 of the mold pin 502, such that the mold compound 216 extends past the bottom of the upper portion 508 of the mold pin 502. After encapsulation, the mold pin 502 is removed from the sub-assembly of FIG. 6, leaving behind a recess or cavity within the mold compound 216 surrounding the P-cell 506 and its associated bond wires 214.

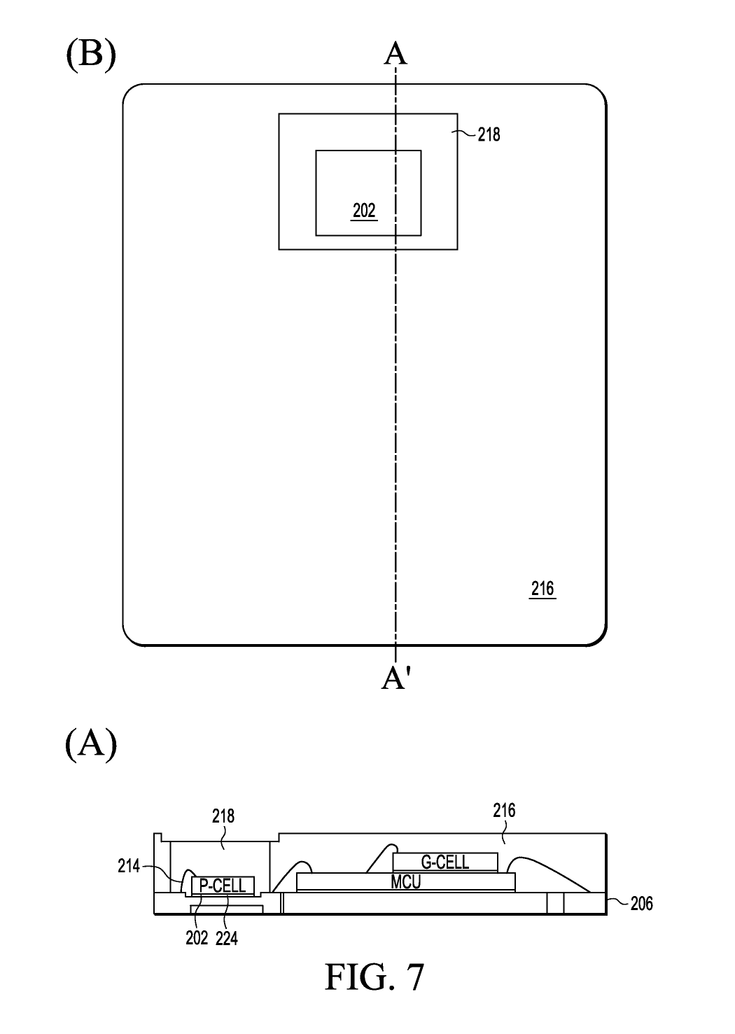

FIGS. 7(A) and 7(B) respectively show a cross-sectional side view and a partial X-ray, top plan view of the sub-assembly of FIG. 6 after the removal of the mold pin 502 and after the subsequent addition of pressure-sensitive gel material 218, which covers the P-cell 202 and its associated bond wires 214. In the implementation shown in FIG. 7, the gel material 218 is applied up to the top of the bottom, smaller-dimensioned portion of the recess formed by the lower portion 504 of the mold pin 502, leaving the top, larger-dimensioned portion of the recess formed by the upper portion 508 of the mold pin 502 unfilled.

Referring again to FIG. 2, after the application of gel material 218, the lid 220 is mounted over the P-cell 202 and gel material 218 to form the final assembly of the sensor device 200. Note that the upper portion 508 of the mold pin 502 has substantially the same outer dimensions as the lid 220 so that the lid 220 fits snugly within the seat formed in mold compound 216 by the upper portion 508. The lid 220 preferably lies flush with a top (outer) surface of the mold compound 216. Note that, for implementations in which the mold pin 502 does not have a larger-dimensioned, upper portion, but rather only a single-dimensioned portion, the lid 220 is fabricated to allow it to be press-fit into the recess formed over the P-cell 202.

The shapes of the leads 210 of the lead frame 206, specifically lead(s) 210A, enable the indirect electrical interconnection of the P-cell 202 and MCU 204 by wire bonding both dies 202, 204 to one or more shared lead(s) 210A. This lead sharing, in turn, allows the mold pin 502 to be placed over the P-cell 202 in a way that does not impinge on either the bond wires 214 connecting the P-cell 202 to shared lead(s) 210A or the bond wires 214 connecting the MCU 204 to the same shared lead(s) 210A. In this way, the bond wires associated with the MCU 204 can be encapsulated by the mold compound 216, while the bond wires associated with the P-cell 202 are covered with the gel material 218. These features enable the sensor device 200 to be manufactured with only a single die-bonding cycle and only a single wire-bonding cycle.

Although not depicted in the drawings, in practice, a plurality of sensor devices are formed simultaneously by using a lead frame sheet that has a two-dimensional array of the lead frames, and then the die bonding and wire bonding steps are performed on all of the lead frames in the array. Similarly, all of the separate devices are encapsulated with the molding compound at the same time too. After assembly, e.g., using the process depicted in FIGS. 3-7, the multiple sensor devices are separated, e.g., in a singulation process involving a saw or laser, to form individual instances of the sensor device 200.

As used herein, the term “mounted to” as in “a first die mounted to a lead frame” covers situations in which the first die is mounted directly to the lead frame with no other intervening dies (as in the mounting of P-cell 202 to lead frame 206 in FIG. 2) as well as situations in which the first die is directly mounted to another die, which is itself mounted directly to the lead frame (as in the mounting of G-cell 208 to lead frame 206 via MCU 204 in FIG. 2). Note that “mounted to” also covers situations in which there are two or more intervening dies between the first die and lead frame.

Although FIG. 2 shows sensor devices 200 having a P-cell and a G-cell, those skilled in the art will understand that, in alternative embodiments, the G-cell and its corresponding bond wires may be omitted.

Although FIG. 2 shows an embodiment in which a G-cell is mounted to the MCU with the electrical interconnection provided by wire-bonding, those skilled in the art will understand that the electrical interconnection between such dies can, alternatively or additionally, be provided by appropriate flip-chip assembly techniques. According to these techniques, two semiconductor dies are electrically interconnected through flip-chip bumps attached to one of the semiconductor dies. The flip-chip bumps may include solder bumps, gold balls, molded studs, or combinations thereof. The bumps may be formed or placed on a semiconductor die using known techniques such as evaporation, electroplating, printing, jetting, stud bumping, and direct placement. The semiconductor die is flipped, and the bumps are aligned with corresponding contact pads of the other die.

By now it should be appreciated that there has been provided an improved packaged semiconductor sensor device and a method of forming the improved packaged semiconductor sensor device. Circuit details are not disclosed because knowledge thereof is not required for a complete understanding of the invention.

Although the invention has been described using relative terms such as “front,” “back,” “top,” “bottom,” “over,” “above,” “under” and the like in the description and in the claims, such terms are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the disclosure is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non enabled embodiments and embodiments that correspond to non statutory subject matter are explicitly disclaimed even if they fall within the scope of the claims.

1. A semiconductor sensor device comprising:
a pre-molded lead frame having a plurality of leads and at least first and second die flags, wherein the first die flag has a cavity formed therein;
a pressure sensor die attached within the cavity of the first die flag, and at least one other die mounted to second die flag;
first bond wires electrically interconnecting the pressure sensor die with first ones of the leads of the lead frame, and second bond wires electrically interconnecting the at least one other die with second ones of the leads of the lead frame;
mold compound encapsulating the at least one other die and the second bond wires;
pressure sensitive gel covering an active region of the pressure sensor die and the first bond wires; and
a lid mounted over the pressure sensor die, wherein the lid has a hole that exposes the gel covered active region of the pressure sensor die to ambient atmospheric pressure outside the sensor device.

2. The sensor device of claim 1, wherein at least one lead of the lead frame is wire bonded to both the pressure sensor die and the at least one other die.

3. The sensor device of claim 1, wherein the lid fits into a seat formed in the mold compound.

4. The sensor device of claim 1, wherein the at least one other die comprises a master control unit (MCU).

5. The sensor device of claim 4, further comprising an acceleration sensor die mounted to the ASIC die, wherein the acceleration sensor die is electrically connected to the MCU with third bond wires.

6. A method for assembling a semiconductor sensor device, the method comprising:
providing a pre-molded lead frame having a first die flag and a second die flag, wherein the first die flag has cavity formed therein;
die bonding a pressure sensor die within the cavity of the first die flag and a master control unit die (MCU) to a surface of the second die flag, wherein die bonding of the pressure sensor die and the MCU is done in a single pass;
electrically connecting the pressure sensor die to first leads of the lead frame with first bond wires, and electrically connecting the MCU to second leads of the lead frame with second bond wires;
placing a mold pin over the pressure sensor die and the first bond wires;
encapsulating the MCU and the second bond wires with a mold compound;
removing the mold pin whereby a recess in the mold compound surrounding the pressure sensor die is formed; and
applying pressure sensitive gel in the recess to cover an active region of the pressure sensor die.

7. The method of claim 6, further comprising:
mounting a lid over the gel-covered pressure sensor die, wherein the lid has a hole that exposes the gel-covered active region of the pressure sensor die to ambient atmospheric pressure outside the sensor device.

8. The method of claim 7, wherein the lid is mounted within recesses in the mold compound such that a top surface of the lid is flush with a top surface of the mold compound.

9. The method of claim 6, further comprising mounting an accelerometer die on a surface of the MCU and electrically connecting the accelerometer die with the MCU with third bond wires.

10. The method of claim 6, wherein the mold pin comprises a lower portion having an outer dimension and defining a cavity and an upper portion having an outer dimension larger than the outer dimension of the lower portion; and
the encapsulating step includes applying the mold compound to a level higher than the lower portion of the mold pin, such that the upper portion forms a seat in the mold compound configured to snugly receive the lid.

11. The method of claim 6, wherein at least one of the first leads is a same lead as one of the second leads.

12. The method of claim 6, further comprising:
separating the sensor device from one or more other instances of the sensor device assembled simultaneously with the sensor device.
